(19) United States
(12) Patent Application Publication
(10) Pub. No.: US 2010/0102399 A1
(43) Pub. Date: Apr. 29, 2010

(54) Methods of Forming Field Effect Transistors and Devices Formed Thereby

(76) Inventors: Sangjin Hyun, Gyeonggi-do (KR); Yugyun Shin, Gyeonggi-do (KR); Hongbae Park, Seoul (KR); Hagju Cho, Gyeonggi-do (KR); Sughun Hong, Gyeonggi-do (KR)

Correspondence Address: MYERS BIGEL SIBLEY & SAJOVEC, PO BOX 37428, RALEIGH, NC, 27627, US

(21) Appl. No.: 12/606,327

(22) Filed: Oct. 27, 2009

(30) Foreign Application Priority Data
Oct. 29, 2008 (KR) 2008-106505

(51) Int. Cl. H01L 29/78; H01L 21/8236

(52) U.S. Cl. 257/402; 438/275; 257/E21.631; 257/E29.255

(57) ABSTRACT

Methods of forming field effect transistors include forming a first gate electrode on a semiconductor substrate and forming insulating spacers on sidewalls of the first gate electrode. At least a portion of the first gate electrode is then removed from between the insulating spacers to thereby expose inner sidewalls of the insulating spacers. Threshold-voltage adjusting impurities are then implanted into the semiconductor substrate, using the insulating spacers as an implant mask. These threshold-voltage adjusting impurities are selected from a group consisting of alkali metals from Group 1 of the periodic chart and halogens from Group 17 of the periodic chart. A second gate electrode is then formed between the inner sidewalls of the insulating spacers.

### REFERENCE TO PRIORITY APPLICATION

This patent application claims priority to Korean Patent Application No. 10-2008-0106505, filed Oct. 29, 2008, the contents of which are hereby incorporated herein by reference.

### FIELD OF THE INVENTION

The present invention relates to methods of forming integrated circuit devices and devices formed thereby and, more particularly, to methods of forming field effect transistors and transistors formed thereby.

### BACKGROUND

Large scale integrated circuit devices typically utilize complementary metal oxide semiconductor (CMOS) technologies to form NMOS and PMOS field effect transistors. However, because the electrical properties of NMOS and PMOS transistors may be compromised when conventional MOS processing techniques are used, advanced processing techniques have been developed to take advantage of the distinct characteristics of N-channel transistors and P-channel transistors. Some of these advanced processing techniques include using threshold voltage adjustment to improve the I-V characteristics of N-channel and P-channel transistors.

### SUMMARY

Methods of forming field effect transistors according to embodiments of the present invention include forming a first gate electrode on a semiconductor substrate and forming insulating spacers on sidewalls of the first gate electrode. At least a portion of the first gate electrode is then removed from between the insulating spacers to thereby expose inner sidewalls of the insulating spacers. Threshold-voltage adjusting impurities are then implanted into the semiconductor substrate, using the insulating spacers as an implant mask. These threshold-voltage adjusting impurities are selected from a group consisting of alkali metals from Group 1 of the periodic chart and halogens from Group 17 of the periodic chart. A second gate electrode is then formed between the inner sidewalls of the insulating spacers.

According to some of these embodiments of the invention, the implanting step may include implanting threshold-voltage adjusting impurities through a remaining portion of the first gate electrode and into the semiconductor substrate. In such embodiments, the step of forming a second gate electrode may include forming a second gate electrode directly on the remaining portion of the first gate electrode.

According to alternative embodiments of the invention, the step of forming a first gate electrode may be preceded by forming a dummy gate insulating layer on the semiconductor substrate. Then, the step of forming a first gate electrode may include forming a dummy gate electrode on the dummy gate insulating layer. According to further aspects of these embodiments of the invention, the removing step includes removing the entire dummy gate electrode from between the insulating spacers and the implanting step includes implanting the threshold-voltage adjusting impurities through the dummy gate insulating layer. These impurities may be implanted at a dose in a range from 1×10¹⁵ cm⁻² to 1×10¹⁷ cm⁻², and at an energy in a range from 1 keV to 50 keV. Thereafter, the step of forming a second gate electrode may be preceded by a step of removing the dummy gate insulating layer from between the insulating spacers. This removal step is followed by a step of depositing a metal oxide layer on the inner sidewalls of the insulating spacers and on a portion of the semiconductor substrate extending between the inner sidewalls of the insulating spacers. The second gate electrode is formed on the deposited metal oxide layer. This metal oxide layer may include a material selected from a group consisting of a metal oxide compound, a metal-semiconductor-oxygen compound and a metal-semiconductor-oxygen-nitrogen compound. The step of forming the second gate electrode includes depositing a gate conductive layer on the metal oxide layer and planarizing the gate conductive layer and the metal oxide layer in sequence to expose the insulating spacers.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1 through 5 are cross-sectional views illustrating a method of forming a semiconductor device according to an embodiment of the present invention.

FIG. 6 is a cross-sectional view of a semiconductor device according to an embodiment of the present invention.

FIG. 7 is a graph illustrating a characteristic of a semiconductor device according to embodiments of the present invention.

FIGS. 8 through 10 are cross-sectional views illustrating a method of forming a semiconductor device according to another embodiment of the present invention.

FIG. 11 is a cross-sectional view of a semiconductor device according to another embodiment of the present invention.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

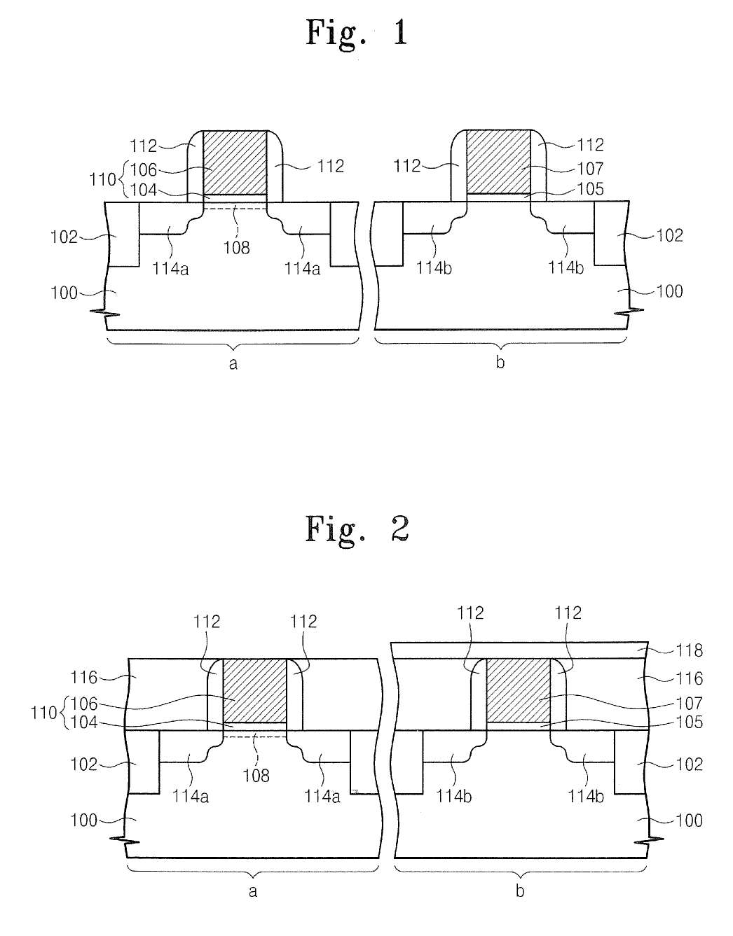

FIGS. 1 through 5 are cross-sectional views illustrating a method of forming a semiconductor device according to an embodiment of the present invention.

Referring to FIG. 1, a device isolation pattern 102 may be formed in a semiconductor substrate 100 including a first region (a) and a second region (b) to define a first active portion and a second active portion. In one embodiment, the semiconductor substrate 100 may be a silicon substrate. In another embodiment, the semiconductor substrate 100 may be a germanium substrate or a silicon-germanium substrate. The first active portion is defined in the first region (a) and the second active portion is defined in the second region (b). The first active portion may correspond to a portion of the semiconductor substrate 100 in the first region (a) surrounded by the device isolation pattern 102. The second active portion may correspond to a portion of the semiconductor substrate 100 in the second region (b) surrounded by the device isolation pattern 102. One of the first region (a) and the second region (b) may be a PMOS region where PMOS transistors are formed and the other may be a NMOS region where NMOS transistors are formed. The first active portion is doped with first type dopants and the second active portion is doped with second type dopants. The device isolation pattern 102 may be formed to be a trench type device isolation pattern. For example, the device isolation pattern 102 may be formed by forming a trench in the substrate 100 and forming an insulating material filling the trench.

A guide pattern 110 crossing the first active portion is formed. A gate pattern crossing the second active portion is formed. The guide pattern 110 may include a dummy dielectric pattern 104 and a dummy gate 106 that are sequentially stacked. The gate pattern may include a gate dielectric pattern 105 and a gate electrode 107. A first channel region 108 is defined in the first active portion under the guide pattern 110. The first channel region 108 may be a portion of the first active portion under the guide pattern 110. Thus, the first channel region 108 may be doped with the first type dopants. A second channel region is defined in the second active portion under the gate electrode 107. The second channel region may be a portion of the second active portion under the gate electrode 107. Thus, the second channel region may be doped with the second type dopants.

The gate electrode 107 may include at least one selected from the group consisting of a doped semiconductor, metal, metal-semiconductor compound (e.g., metal silicide) and conductive metal nitride. The gate electrode 107 may include conductive material having a work function required by a transistor formed in the second region (b). In one embodiment, in case that the second region (b) is an NMOS region, the gate electrode 107 may include conductive material having a work function relatively close to a conduction band edge among a conduction band edge and a valence band edge of a semiconductor (e.g., silicon) constituting the semiconductor substrate 100. In another embodiment, In case that the second region (b) is an PMOS region, the gate electrode 107 may include conductive material having a work function relatively close to a valence band edge among the conduction band edge and the valence band edge of the semiconductor (e.g., silicon). The gate dielectric pattern 105 may include at least one selected from the group consisting of thermal oxide, thermal oxynitride, metal oxide (e.g., aluminum oxide or hafnium oxide), metal-semiconductor-oxygen compound (hafnium silicate) and metal-semiconductor-oxygen-nitrogen compound (e.g., hafnium-silicon-oxygen-nitrogen compound). The guide pattern 110 and the gate pattern 105 and 107 may be simultaneously formed or may be sequentially formed.

A first source/drain 114a is formed in the first active portion of both sides of the guide pattern 110. The first source/drain 114a is doped with the second type dopants. The second type dopants in the first source/drain 114a are opposite to the first type dopants doped in the first channel region 108. A second source/drain 114b is formed in the second active portion of both sides of the gate electrode 107. The second source/drain 114b may be doped with the first type dopants. The first type dopants in the second source/drain 114b are opposite to the second type dopants doped in the second channel region. One of the first type dopant and the second type dopant is an n-type dopant (e.g., phosphorus (P) or arsenic (As)) and the other is a p-type dopant (e.g., boron (B)). The first source/drain 114a and the second source/drain 114b may be sequentially formed. For example, after forming the first source/drain 114a, the second source/drain 114b may be formed. In contrast, after forming the second source/drain 114b, the first source/drain 114a may be formed. A gate spacer 112 may be formed on both sidewalls of the guide pattern 110 and the gate electrode 107. The first and second sources/drains 114a and 114b may be formed to have a lightly doped drain (LDD) structure using the gate spacer 112.

Referring to FIG. 2, an interlayer insulating layer is formed on the semiconductor substrate 100. The interlayer insulating layer is planarized until a top surface of the guide pattern 110 is exposed. At this time, the gate pattern of the second region (b) (i.e., a top surface of the gate electrode 107) may be exposed. A top surface of the planarized interlayer insulating layer 116 may be coplanar with the exposed top surface of the guide pattern 110. The dummy gate 106 of the guide pattern 110 may include a material having an etching selectivity with respect to the interlayer insulating layer 116. The dummy gate 106 may be formed of the same material as the gate electrode 107 in the second region (b). In this case, the dummy gate 106 and the gate electrode 107 may be simultaneously formed.

A mask pattern 118 is formed on the semiconductor substrate 100 including the planarized interlayer insulating layer 116. The mask pattern 118 may be formed in the second region (b) to cover the exposed gate electrode 107 in the second region (b). At this time, the top surface of the guide pattern 110 in the first region (a) is exposed. The mask pattern 118 may be formed of photoresist and/or hard mask material (e.g., nitride or oxynitride).

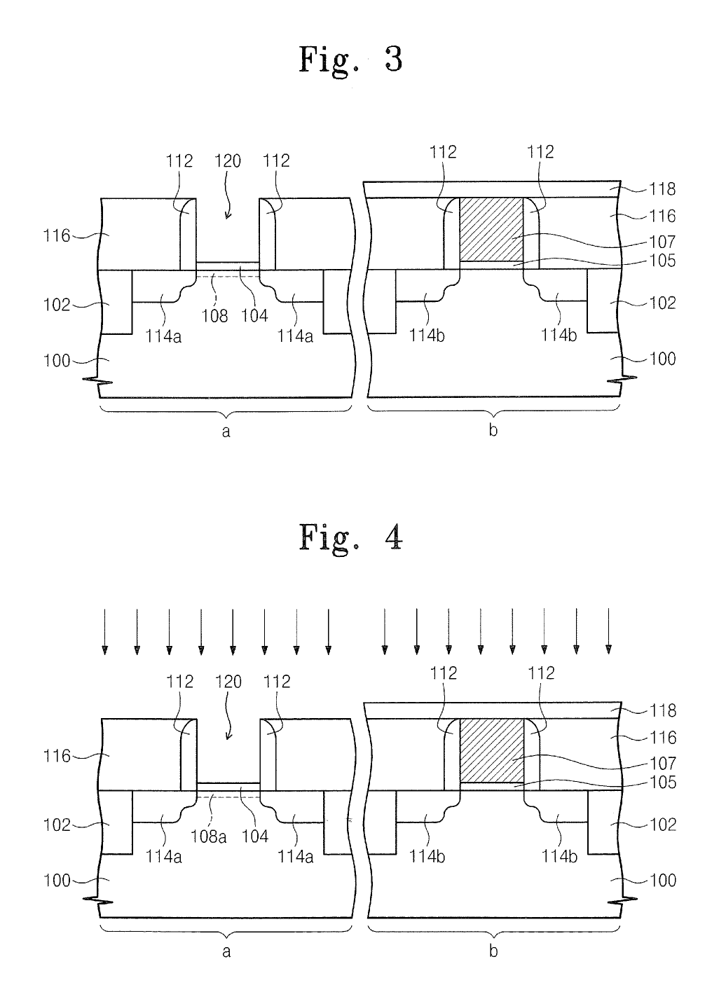

Referring to FIG. 3, the guide pattern 110 is etched using a selective etching process to form a groove 120. The groove 120 may be formed by removing the dummy gate 106. In this case, the dummy dielectric pattern 104 may remain under the groove 120. Unlike this, the groove 120 may be formed by removing the dummy gate 106 and the dummy dielectric pattern 104. In this case, the groove 120 may expose the channel region 108. During formation of the groove 120, the gate electrode 107 in the second region (b) is protected by the mask pattern 118.

Referring to FIG. 4, impurities for controlling a threshold voltage are supplied to the first channel region 108. A reference numeral “108a” in FIG. 4 represents the first channel region 108a where the impurities are supplied. The impurities may be supplied to the first channel region 108 by an ion implantation process. More specifically, the impurities of ion state (hereinafter it is referred to as impurity ions) are implanted into the semiconductor substrate 100 including the groove 120. The impurity ions are supplied to the first channel region 108 with a self aligned method by the groove 120 and the interlayer insulating layer 116 of the first region (a). That is, the impurity ions are not implanted into the first source/drain 114a by the interlayer insulating layer 116. The impurity ions are also not implanted into the second channel region and second source/drain 114b by the mask pattern 118, the interlayer insulating layer 116 and the gate electrode 107 in the second region (b). In other words, the impurity ions are self aligned with the groove 120, thereby being implanted only into the first channel region 108. After implanting the impurity ions, an annealing process may be performed on the semiconductor substrate 100. Impurities in the first channel region 108a may be activated by the annealing process.

As described above, the first channel region 108a is doped with the first type dopants and may also include the impurities to control a threshold voltage of a transistor formed in the first region (a). The first type dopants activated in the first channel region 108a are substituted with semiconductor atoms of a semiconductor latticed structure. Similarly, the second type dopants activated in the first source/drain 114a are also substituted with semiconductor atoms of a semiconductor latticed structure. Unlike the activated first type dopants and second type dopants, the supplied impurities include interstitial impurities activated at an interstitial position of a latticed structure in the first channel region 108a. The interstitial impurities may be activated at an interstitial position corresponding to a tetrahedral coordination of the latticed structure. That is, an activation mechanism of the first type and second type dopants is different from an activation mechanism of the impurities. The impurities do not include an n-type dopant and a p-type dopant. The supplied impurities can reduce an absolute value of a threshold voltage of the transistor. The activated interstitial impurities exist as an ion state to have charges. A threshold voltage of the transistor may be controlled by the interstitial impurities.

In case that the first region (a) is a PMOS region and the second region (b) is an NMOS region, the first type dopants are n-type dopants and the second type dopants are p-type dopants. The impurities may be a halogen group element. Thus, interstitial impurities in the first channel region 108a may capture electrons which are majority carriers in the first channel region 108a to have negative charge. As a result, a threshold voltage of a PMOS transistor formed in the first region (a) is controlled. In particular, an absolute value of a threshold voltage of a PMOS transistor formed in the first region (a) may be reduced. For example, when the first region (a) is a PMOS, the impurities may be fluorine (F).

It is preferable that the amount of impurities supplied to the first channel region 108a is sufficient to control the threshold voltage. When the impurities are injected by an ion implantation process, the amount of dose of the impurity ions may be about 1×10¹⁵/cm² to about 1×10¹⁷/cm². In this case, the impurity ions may be fluorine (F) ions. The impurity ions may be implanted with an implanting energy of about 1 keV to about 50 keV.

In case that the first region (a) is an NMOS region and the second region (b) is a PMOS region, the first type dopants are p-type dopants and the second type dopants are an n-type dopants. At this time, the impurities may be first group element of a periodic table. In this case, the most outer electrons of the interstitial impurities may combine with majority carriers in the first channel region 108a. Accordingly, a threshold voltage of a transistor formed n the first region (a) can be controlled.

When implanting the impurity ions, the dummy dielectric pattern 104 remaining under the groove 120 may be used as an ion implantation buffer layer. When the groove 120 is formed by removing the dummy gate 106 and the dummy dielectric pattern 104, a buffer oxide layer may be formed on the first channel region 108 exposed by the groove 120 before implanting the impurity ions.

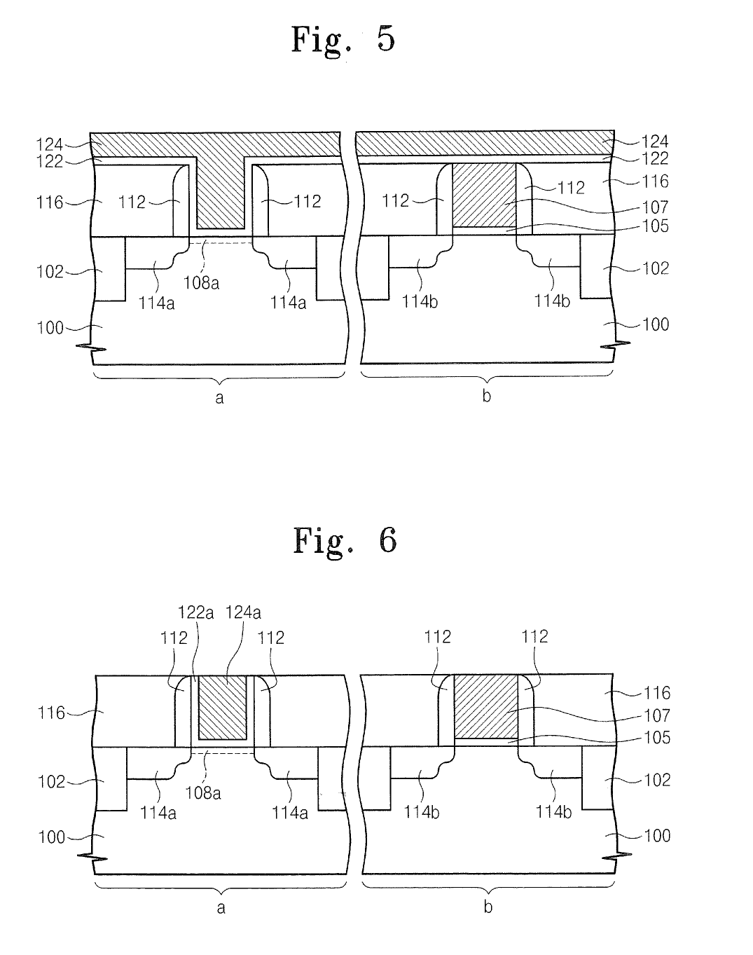

Referring to FIG. 5, after supplying the impurities, the first channel region 108a under the groove 120 is exposed. The first channel region 108a under the groove 120 may be exposed by removing the remaining dummy dielectric pattern 104 or the buffer oxide layer.

A gate dielectric layer 122 is formed on the exposed first channel region 108a. The gate dielectric layer 122 may include a high dielectric layer having a high dielectric constant. For example, the gate dielectric layer 122 may include at least one of metal oxide (e.g., aluminum oxide or hafnium oxide), metal-semiconductor-oxygen compound (hafnium-silicon-oxygen compound) and metal-semiconductor-oxygen-nitrogen compound (e.g., hafnium-silicon-oxygen-nitrogen compound). The gate dielectric layer 122 may be conformally on an entire surface of the semiconductor substrate 100 including the groove 120 using a process such as a chemical vapor deposition (CVD) or an atomic layer deposition (ALD). Before forming the gate dielectric layer 122, an interface layer (not shown) may be formed on the exposed first channel region 108a. The interface layer may be formed of thermal oxide or thermal oxynitride.

Before forming the gate dielectric layer 122, the mask pattern 118 on the second region (b) may be removed. Thus, the gate dielectric layer 122 of the second region (b) may be formed on the interlayer insulating layer 116 and the gate electrode 107. When the mask pattern 118 is formed of hard mask material, the gate dielectric layer 122 of the second region (b) may be formed on the mask pattern 118.

According to an embodiment of the present invention, the gate dielectric layer 122 may be formed using a process such as a thermal oxidation and/or a thermal nitration. In this case, the gate dielectric layer 122 may be formed limitedly on the exposed first channel region 108a.

A gate conductive layer 124 is formed on the gate dielectric layer 122. The gate conductive layer 124 may fill the groove 120. The gate conductive layer 124 may include conductive material having a work function required by a transistor formed in the first region (a). In one embodiment, in case that the first region (a) is a PMOS region, the gate conductive layer 124 may include a conductive material having a work function adjacent to an energy level of a valence band edge of a semiconductor constituting the semiconductor substrate 100. In another embodiment, in case that the first region (a) is an NMOS region, the gate conductive layer 124 may include a conductive material having a work function adjacent to an energy level of a conduction band edge of a semiconductor constituting the semiconductor substrate 100.

The gate conductive layer 124 and the gate dielectric layer 122 are planarized down to the top surface of the interlayer insulating layer to form a gate dielectric pattern (122a of FIG. 6) and a gate electrode (124a of FIG. 6) in the groove 120. At this time, the gate dielectric layer 122 and the gate conductive layer 124 of the second region (b) may be removed. When the mask pattern 118 is under the gate dielectric layer 122 of the second region (b), the mask pattern 118 may be removed after the gate dielectric layer 122 of the second region (b) is removed.

According to the method of forming a semiconductor device described above, impurities different from dopants of a p-type and an n-type are supplied to the first channel region 108 to control a threshold voltage of a transistor formed in the first region (a). The supplied impurities include interstitial impurities activated at an interstitial location of a semiconductor latticed structure in the first channel region 108a. The interstitial impurities may have a diffusion coefficient lower than the n-type dopant and the p-type dopant. Accordingly, a diffusion of interstitial impurities in the first channel region 108a into the first active portion under the first channel region 108a can be minimized. As a result, the first active portion under the first channel region 108a and between the first sources/drains 114a has a sufficient majority carrier concentration to minimize a deterioration of a punch characteristic between the first sources/drains 114a. In other words, the supplied impurities not only can control the threshold voltage but also can minimize a deterioration of a punch characteristic between the first sources/drains 114a.

If the second type dopants opposite to the first type dopants may be supplied to the first channel region 108 doped with the first type dopants to control a threshold voltage of a transistor, the supplied second type dopants may be diffused under the first channel region 108 due to a thermal budget. As a result, a concentration of majority carriers of the first active portion under the first channel region 108 may be reduced to deteriorate a punch characteristic between the first sources/drains 114a. However, according to embodiments of the present invention, the impurities different from p-type and n-type dopants are supplied to the first channel region 108 not only to control the threshold voltage but also to minimize a deterioration of a punch characteristic between the first sources/drains 114a.

Also, the impurities are supplied to the first channel region 108 using a selective injection method. In particular, the impurities are supplied to the first channel region 108 through the groove 120 with a self aligned method. Accordingly, the impurities are not supplied to the first sources/drains 114a. As a result, a deterioration phenomenon which may be caused by an interaction between the impurities and the second type dopants in the first sources/drains 114a may be minimized.

If the impurities are supplied to the first sources/drains 114a to act to the second type dopants, a resistance of the first source/drain 114a may increases or a characteristic of a leakage current may deteriorate. However, according to embodiments of the present invention, the impurities are supplied to the first channel region 108 with a self aligned method, thereby minimizing a supply of the impurities to the first sources/drains 114a. As a result, an increase of a resistance of the first source/drain 114a and/or a deterioration of a characteristic of a leakage current may be minimized.

In addition, since the first channel region 108a to which the impurities are supplied includes the interstitial impurities, the second type dopants in the first sources/drains 114a may be suppressed to diffuse to the first region 108a. As a result, a reduction of a channel length of the first channel region 114a may be minimized.

Consequently, a semiconductor device which is optimized to a high integration and has superior reliability can be embodied.

FIG. 6 is a cross-sectional view of a semiconductor device according to an embodiment of the present invention.

Referring to FIG. 6, a device isolation pattern 102 defining a first active portion and a second active portion is disposed in a semiconductor substrate 100. The first active portion is defined in a first region (a) of the semiconductor substrate 100 and the second active portion is defined in a second region (b) of the semiconductor substrate 100. The first active portion may be a portion of the semiconductor substrate 100 surrounded by the device isolation pattern 102 in the first region (a). The first active portion is doped with first type dopants. The second active portion may be a portion of the semiconductor substrate 100 surrounded by the device isolation pattern 102 in the second region (b). The second active portion is doped with second type dopants. Any one of the first region (a) and the second region (b) is an NMOS region and the other is a PMOS region.

A first gate electrode 124a crosses over the first active portion and a first gate dielectric pattern 122a is disposed between the first gate electrode 124a and the first active portion. The first gate dielectric pattern 122a may extend to cover both sidewalls of the first gate electrode 124a. A first channel region 108a is defined under the first gate electrode 124a. The first channel region 108a is a portion of the first active portion. First sources/drains 114a are disposed in the first active portion of both sides of the first gate electrode 124a. The first sources/drains 114a are doped with the second type dopants.

A second gate electrode 107 crosses over the second active portion and a second gate dielectric pattern 105 is disposed between the second gate electrode 107 and the second active portion. A second channel region which is a portion of the second active portion is defined under the second gate electrode 107. Second sources/drains 114b are disposed in the second active portion of both sides of the second gate electrode 107. One of the first type dopant and the second type dopant is an n-type dopant and the other is a p-type dopant.

A gate spacer 112 may be disposed on both sidewalls of the first gate electrode 124a and on both sidewalls of the second gate electrode 107. In case that the first gate dielectric pattern 122a extends to cover both sidewalls of the first gate electrode 124a, an extension portion of the first gate dielectric pattern 122a may be disposed between the gate spacer 112 and the first gate electrode 124a.

The first channel region 108a includes the first type dopants and impurities. The first type dopants activated in the first channel region 108a are substituted to semiconductor atoms of a semiconductor latticed structure. Impurities in the first channel region 108a include interstitial impurities activated at an interstitial location of the semiconductor latticed structure. The impurities may not include an n-type dopant and a p-type dopant. A concentration of the impurities in the first channel region 108a may be about 2×10²⁰/cm³ to about 2×10²²/cm³. As described referring to FIGS. 1 through 5, since the impurities are supplied to the first channel region 108a with a self aligned method, the first source/drain 114a may not include the impurities. In particular, at least a central part of the first source/drain 114a does not include the impurities. For example, a portion of the first source/drain 114a being in contact with a contact plug (not shown) does not include the impurities.

An interlayer insulating layer 116 is disposed on the substrate 100. The interlayer insulating layer 116 covers the first and second sources/drains 114a and 114b and the device isolation pattern 102. A top surface of the interlayer insulating layer 116 may be coplanar with a top surface of the first gate electrode 124a. Also, the top surface of the interlayer insulating layer 116 may be coplanar with a top surface of the second gate electrode 107.

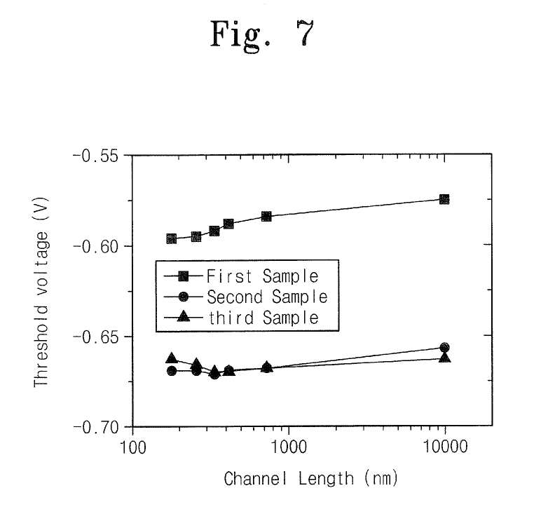

Next, a characteristic of a semiconductor device according to an embodiment of the present invention is described referring to a graph of FIG. 7. FIG. 7 represents a threshold voltage of transistors according to an experiment.

FIG. 7 is a graph illustrating a characteristic of a semiconductor device according to embodiments of the present invention. An x axis of the graph represents a channel length and a y axis represents a threshold voltage of a transistor.

Referring to FIG. 7, a first sample, a second sample, and a third sample were prepared for an experiment. The first sample includes a plurality of PMOS transistors formed in a substrate. The PMOS transistors of the first sample have different channel lengths from one another. Gate dielectric layers of the PMOS transistors of the first sample are formed to have the same material and same thickness. Similarly, each of the second and third samples includes a plurality of PMOS transistors. The PMOS transistors of the second and third samples are formed to have the same gate dielectric layers and channel lengths as the PMOS transistors of the first sample, respectively.

Fluorine ions of dose of 2×10¹⁵/cm³ were implanted into channel regions of the PMOS transistors of the first sample. Fluorine ions of dose of 5×10¹⁴/cm³ were implanted into channel regions of the PMOS transistors of the second sample. Fluorine ions were not implanted into channel regions of the PMOS transistors of the third sample. Threshold voltages of the PMOS transistors of the first, second and third samples are depicted in FIG. 7. In FIG. 7, squares represent threshold voltages of the PMOS transistors of the first sample and circles represent threshold voltages of the PMOS transistors of the second sample. Triangles represent threshold voltages of the PMOS transistors of the third sample.

As depicted in FIG. 7, absolute values of the threshold voltages of the PMOS transistors of the first sample (2×10¹⁵/cm³) are reduced compared with the threshold voltages of the PMOS transistors of the third sample. Consequently, in can be appreciated that the threshold voltages were controlled by supplying the impurities (e.g., fluorine) different from the n-type and the p-type dopants to the channel regions.

The threshold voltages of the PMOS transistors of the second sample (5×10¹⁴/cm³) are similar to the threshold voltages of the PMOS transistors of the third sample. That is, the threshold voltages of the PMOS transistors of the second sample may be not controlled. Consequently, it can be appreciated that impurities according to embodiments of the present invention be sufficiently supplied to the channel regions to control a threshold voltage of a transistor.

In the present embodiment, elements identical to the first embodiment described above use identical reference numerals.

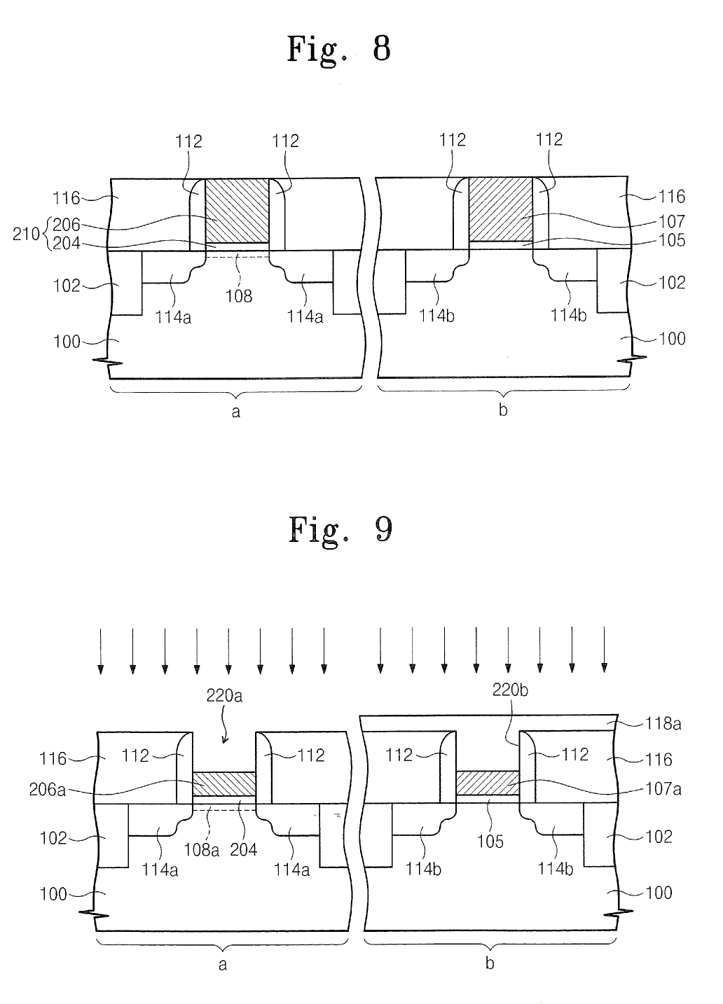

FIGS. 8 through 10 are cross-sectional views illustrating a method of forming a semiconductor device according to another embodiment of the present invention.

Referring to FIG. 8, a device isolation pattern 102 is formed in a semiconductor substrate 100 to define a first active portion of a first region (a) and a second active portion of a second region (b). The first active portion is doped with first type dopants and the second active portion is doped with second type dopants. A guide pattern 210 crossing the first active portion is formed. The guide pattern 210 includes a first gate dielectric pattern 204 and a first gate electrode 206 that are sequentially stacked. A first channel region 108 is defined in the first active portion under the first gate electrode 206. The first channel region 108 corresponds to a portion of the first active portion. A second gate dielectric pattern 105 and a second gate electrode 107 that are sequentially stacked on the second active portion are formed. The second gate electrode 107 crosses over the second active portion and the second gate dielectric pattern 105 is disposed between the second gate electrode 107 and the second active portion. A second channel region is defined in the second active portion under the second gate electrode 107. The second channel region corresponds to a portion of the second active portion.

One of the first and second gate electrodes 206 and 107 may include conductive material having a work function required by an NMOS transistor and the other may include conductive material having a work function required by a PMOS transistor. The first and second gate dielectric patterns 204 and 105 may be formed of different material or the same material.

An embodiment of method of forming the guide pattern 210 and the second gate electrode 107 is described. First, a first gate dielectric layer, a first gate conductive layer and an etch stop layer may be sequentially formed on an entire surface of the semiconductor substrate 100 including the first and second active portions. And then, an etch stop layer, a first gate conductive layer and a first gate dielectric layer in the second region (b) may be removed to expose the second active portion. At this time, an etch stop layer, a first gate conductive layer and a first gate dielectric layer in the first region (a) remain. Subsequently, a second gate dielectric layer and a second conductive layer may be sequentially formed on an entire surface of the semiconductor substrate 100. A second gate conductive layer, a second gate dielectric layer and the etch stop layer in the first region (a) are removed. At this time, a second gate conductive layer and a second gate dielectric layer in the second region (b) remain. The first gate conductive layer and the first gate dielectric layer in the first region (a) may be successively patterned to form the guide pattern 210. The second gate conductive layer and the second gate dielectric layer in the second region (b) may be successively patterned to form the second gate dielectric pattern 105 and the second gate electrode 107. As a result, the first and second gate electrodes 206 and 107 may be formed to have different material from each other. However, the present invention does not limit to here. The first and second gate electrodes 206 and 107 may be formed using different methods.

A first source/drain 114a doped with second type dopants is formed in the first active portion of both sides of the guide pattern 210. A second source/drain 114b doped with first type dopants is formed in the second active portion of both sides of the second gate electrode 107. Gate spacers 112 are formed on both sidewalls of the guide pattern 210 and on both sides of the second gate electrode 107. The first and second sources/drains 114a and 114b may be formed to have a lightly doped drain (LDD) structure using the gate spacer 112.

An interlayer insulating layer is formed on an entire surface of the semiconductor substrate 100 and then, the interlayer insulating layer is planarized until top surfaces of the guide pattern 210 and the second gate electrode 107 are exposed. Thus, a top surface of the planarized interlayer insulating layer 116 may be coplanar with the top surfaces of the guide pattern 210 and the second gate electrode 107.

Referring to FIG. 9, the guide pattern 210 is etched to form a first groove 220a. Specifically, a top surface of the first gate electrode 206 may be etched to form the first groove 220a. At this time, a lower portion of the first gate electrode 206 may remain. That is, the first groove 220a may be formed by removing an upper portion of the first gate electrode 206. The first groove 220a exposes the etched first gate electrode 206a. When forming the first groove 220a, a top surface of the second gate electrode 107 may be etched to form a second groove 220b. The second groove 220b may expose the etched second gate electrode 107a. One of the etched first and second gate electrodes 206a and 107a may include conductive material having a work function required by an NMOS transistor and the other may include conductive material having a work function required by a PMOS transistor.

A mask pattern 118a is formed on the semiconductor substrate 100. The mask pattern 118a may be formed in the second region (b) to cover the etched second gate electrode 107a and the interlayer insulating layer 116 of the second region (b). The mask pattern 118a may fill the second groove 220b. At this time, the first groove 220a is exposed.

According to an embodiment of the present invention, the mask pattern 118a may be formed before forming the first groove 220a. In this case, the second groove 220b may not be formed. For example, after forming the mask pattern 118a covering the second gate electrode 107, the first gate electrode 206 is etched to form the first groove 220a.

Referring to FIG. 9, impurities for controlling a threshold voltage are supplied to the first channel region 108 of the semiconductor substrate 100 including the first groove 220a and the mask pattern 118a. The impurities may be supplied by an ion implantation process. In the first region (a), a bottom surface of the first groove 220a is lower than a top surface of the planarized interlayer insulating layer 116. Accordingly, the impurities may be supplied to the first channel region 108 with a self aligned method. The planarized interlayer insulating layer 116 blocks the impurities to prevent the impurities from being supplied into the first source/drain 114a. The impurities may be identical to those of the first embodiment described above. Since the etched first gate electrode 206a remains under the first groove 220a, an ion implantation energy of the impurities may be greater than that of the first embodiment. Other characteristics of the impurities may be identical to the first embodiment described above except the ion implantation energy.

After supplying the impurities, an annealing process may be performed. The impurities can be activated in the first channel region 108a by the annealing process. The impurities which will be supplied to the first channel region 108a can also be activated by a heat of a process temperature of subsequent processes without the annealing process.

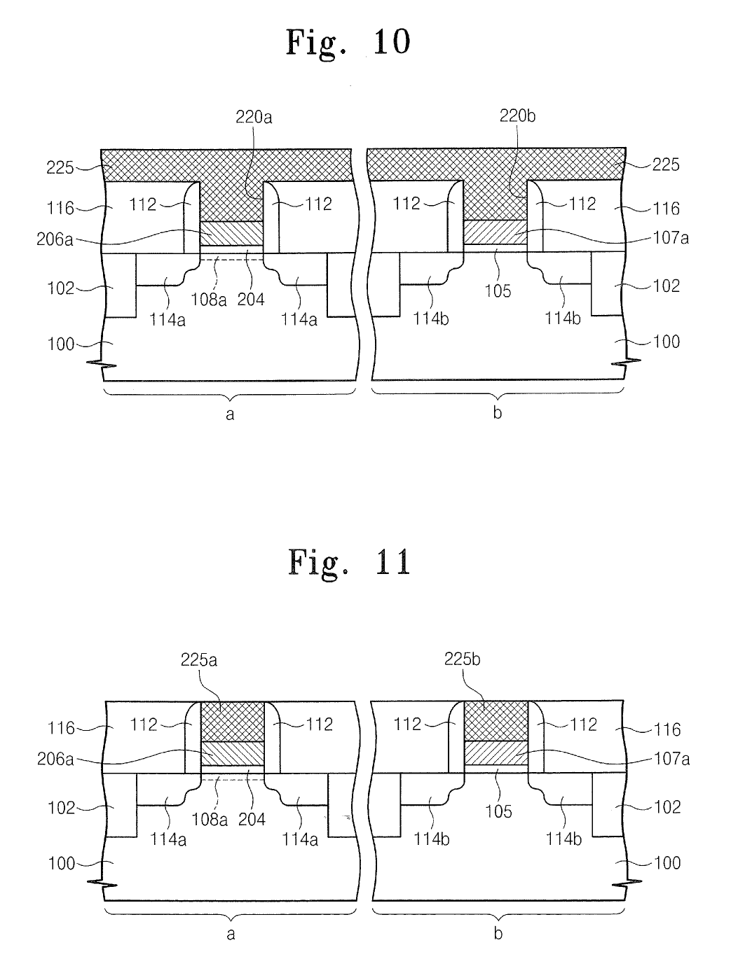

Referring to FIG. 10, after supplying the impurities, the mask pattern 118a may be removed to expose the second groove 220b. A low resistance conductive layer 225 filling the first and second grooves 220a and 220b may be formed on an entire surface of the semiconductor substrate 100. The low resistance conductive layer 225 may include a conductive material having a resistivity lower than the first gate electrode 206a. The low resistance conductive layer 225 may also include a conductive material having a resistivity lower than the second gate electrode 107a. For example, the low resistance conductive layer 225 may include at least one selected from the group consisting of tungsten, copper, aluminum and metal-semiconductor compound. The low resistance conductive layer 225 is planarized down to the top surface of the interlayer insulating layer 116 to form a first capping pattern 225a and a second capping pattern 225b of FIG. 11. When the second groove 220b is not formed, the second capping pattern 225 may be omitted.

According to an embodiment of the present invention, a capping insulating layer filling the first and second grooves 220a and 220b instead of the low resistance conductive layer 225 may be formed on an entire surface of the semiconductor substrate 100 and then, the capping insulating layer may be planarized down to the top surface of the interlayer insulating layer. Thus, the first and second capping patterns 225a and 225b may be formed of an insulating material. In this case, the first and second capping patterns 225a and 225b may include an insulting material having an etching selectivity with respect to the interlayer insulating layer 116. For example, the interlayer insulating layer 116 may be formed of a material such as oxide and the first and second capping patterns 225 and 225b may be formed of a material such as nitride and/or oxynitride.

FIG. 11 is a cross-sectional view of a semiconductor device according to another embodiment of the present invention.

Referring to FIG. 11, a device isolation pattern 202 is disposed in a semiconductor substrate 100 including a first region (a) and a second region (b). The device isolation pattern 102 defines a first active portion in the first region (a) and a second active portion in the second region (b). The first active portion is doped with first type dopants and the second active portion is doped with second type dopants.

A first gate electrode 206a crosses over the first active portion and a first gate dielectric pattern 204 may be disposed between the first gate electrode 206a and the first active portion. A first capping pattern 225a may be disposed on the first gate electrode 206a. The first capping pattern 225a may have both sidewalls aligned with both sidewalls of the first gate electrode 206. For example, the both sidewalls of the first capping pattern 225a may be coplanar with the both sidewalls of the first gate electrode, respectively. A first source/drain 114a doped with second type dopants is disposed in the first active portion of both sides of the first gate electrode 206a. A first channel region 108a is defined in the first active portion under the first gate electrode 206a. The first channel region 108a includes first type dopants and impurities for controlling a threshold voltage. The first type dopants activated in the first channel region 108a are substituted with semiconductor atoms in a semiconductor latticed structure and the impurities include interstitial impurities activated at an interstitial position of the semiconductor latticed structure in the first channel region 108a. Other features of the first channel region 108a are omitted because those were described in the first embodiment.

A second gate electrode 107a crosses over the second active portion and a second gate dielectric pattern 105 may be disposed between the second gate electrode 107a and the second active portion. A second capping pattern 225b may be disposed on the second gate electrode 107a. The second capping pattern 225b may have both sidewalls aligned with both sidewalls of the second gate electrode 107a. A second source/drain 114b doped with the first type dopants is disposed in the second active portion of both sides of the second gate electrode 107a. A second channel region doped with the second type dopants is defined in the second active portion under the second gate electrode 107a.

Gate spacers 112 may be disposed on both sidewalls of the first gate electrode 206a and the first capping pattern 225a and both sidewalls of the second gate electrode 107a and the second capping pattern 225b. An interlayer insulating layer 116 covers the first and second sources/drains 114a and 114b and the device isolation pattern 102. A top surface of the interlayer insulating layer 116 may be coplanar with top surfaces of the first and second capping patterns 225a and 225b.

The first capping pattern 225a may include a conductive material having a low resistivity compared with the first gate electrode 206a. Unlike this, the first capping pattern 225a may include an insulating material having an etching selectivity with respect to the interlayer insulating layer 116. The first and second capping patterns 225a and 225b may be formed of the same material. The second capping pattern 225b may be omitted. When the second capping pattern 225b is omitted, a top surface of the second gate electrode 107a may be coplanar with the top surface of the interlayer insulating layer 116 and the top surface of the first capping pattern 225a.

Thus, as described hereinabove, methods of forming field effect transistors according to embodiments of the present invention include forming a first gate electrode 106 on a semiconductor substrate 100 and forming insulating spacers 112 on sidewalls of the first gate electrode 106, as illustrated by FIG. 1. As illustrated by FIG. 3, at least a portion of the first gate electrode 106 is then removed from between the insulating spacers 112 to thereby expose inner sidewalls of the insulating spacers 112. Threshold-voltage adjusting impurities are then implanted into the semiconductor substrate 100, using the insulating spacers as an implant mask, as illustrated by FIG. 4. These threshold-voltage adjusting impurities may be selected from a group consisting of alkali metals from Group 1 of the periodic chart and halogens from Group 17 of the periodic chart. A second gate electrode 124a is then formed between the inner sidewalls of the insulating spacers 112.

As illustrated by FIGS. 9-11, the implanting step may include implanting threshold-voltage adjusting impurities through a remaining portion of the first gate electrode 206a and into the semiconductor substrate 100. In such embodiments, the step of forming a second gate electrode may include forming a second gate electrode 225a directly on the remaining portion of the first gate electrode 206.

According to the embodiments of the invention illustrated by FIGS. 1-6, the step of forming a first gate electrode may be preceded by forming a dummy gate insulating layer 104 on the semiconductor substrate. Then, the step of forming a first gate electrode may include forming a dummy gate electrode 106 on the dummy gate insulating layer 104. According to further aspects of these embodiments of the invention illustrated by FIGS. 3-4, the removing step includes removing the entire dummy gate electrode 106 from between the insulating spacers 112 and the implanting step includes implanting the threshold-voltage adjusting impurities through the dummy gate insulating layer 104. These impurities may be implanted at a dose in a range from 1×10¹⁵ cm⁻² to 1×10¹⁷ cm⁻², and at an energy in a range from 1 keV to 50 keV. Thereafter, the step of forming a second gate electrode 124a may be preceded by a step of removing the dummy gate insulating layer 104 from between the insulating spacers 112. As illustrated by FIG. 5, this removal step is followed by a step of depositing a metal oxide layer 122 on the inner sidewalls of the insulating spacers 112 and on a portion of the semiconductor substrate 100 extending between the inner sidewalls of the insulating spacers 112. The second gate electrode 124a is formed on the deposited metal oxide layer 122. This metal oxide layer may include a material selected from a group consisting of a metal oxide compound, a metal-semiconductor-oxygen compound and a metal-semiconductor-oxygen-nitrogen compound. The step of forming the second gate electrode 124a includes depositing a gate conductive layer 124 on the metal oxide layer 122 and planarizing the gate conductive layer 124 and the metal oxide layer 122 in sequence to expose the insulating spacers 112.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of forming a field effect transistor, comprising:
forming a first gate electrode on a semiconductor substrate;
forming insulating spacers on sidewalls of the first gate electrode;
removing at least a portion of the first gate electrode from between the insulating spacers to thereby expose inner sidewalls of the insulating spacers;
implanting threshold-voltage adjusting impurities into the semiconductor substrate, using the insulating spacers as an implant mask, said threshold-voltage adjusting impurities selected from a group consisting of alkali metals and halogens; and
forming a second gate electrode between the inner sidewalls of the insulating spacers.

2. The method of claim 1, wherein said forming a first gate electrode comprises forming a dummy gate electrode on the semiconductor substrate; and wherein said removing comprises removing the entire dummy gate electrode from between the insulating spacers.

3. The method of claim 1, wherein said implanting comprises implanting threshold-voltage adjusting impurities through a remaining portion of the first gate electrode and into the semiconductor substrate; and wherein said forming a second gate electrode comprises forming a second gate electrode directly on the remaining portion of the first gate electrode.

4. The method of claim 1, wherein said implanting comprises implanting the threshold-voltage adjusting impurities at a dose in a range from 1×10¹⁵ cm⁻² to 1×10¹⁷ cm⁻².

5. The method of claim 1, wherein said implanting comprises implanting the threshold-voltage adjusting impurities at a dose in a range from 1×10¹⁵ cm⁻² to 1×10¹⁷ cm⁻², and at an energy in a range from 1 keV to 50 keV.

6. The method of claim 1, wherein said forming a first gate electrode is preceded by forming a dummy gate insulating layer on the semiconductor substrate; and wherein said implanting comprises implanting the threshold-voltage adjusting impurities through the dummy gate insulating layer.

7. The method of claim 1, wherein said forming a first gate electrode is preceded by forming a dummy gate insulating layer on the semiconductor substrate; and wherein said forming a second gate electrode is preceded by removing the dummy gate insulating layer from between the insulating spacers.

8. The method of claim 7, wherein said forming a second gate electrode is preceded by depositing a metal oxide layer on the inner sidewalls of the insulating spacers and on a portion of the semiconductor substrate extending between the inner sidewalls of the insulating spacers; and wherein said forming a second gate electrode comprises forming the second gate electrode on the metal oxide layer.

9. The method of claim 8, wherein the metal oxide layer comprises a material selected from a group consisting of a metal oxide compound, a metal-semiconductor-oxygen compound and a metal-semiconductor-oxygen-nitrogen compound.

10. The method of claim 8, wherein said forming a second gate electrode comprises:
depositing a gate conductive layer on the metal oxide layer; and
planarizing the gate conductive layer and the metal oxide layer in sequence to expose the insulating spacers.

11. A method of forming a semiconductor device comprising:
defining a channel region doped with first type-dopants in a semiconductor substrate;
forming a source/drain doped with second type dopants in a semiconductor substrate of both sides of the channel region; and
supplying impurities for controlling a threshold voltage to the channel region using a selective injection method,
wherein the first type dopants activated in the channel region are substituted with semiconductor atoms of a semiconductor latticed structure and the supplied impurities include interstitial impurities activated at an interstitial location of the semiconductor latticed structure.

12. The method of claim 11, wherein the first type dopants are n-type dopants, the second type dopants are p-type dopants, and the impurities are a halogen group element.

13. The method of claim 11, further comprising: after supplying the impurities to the channel region, performing an annealing process on the substrate.

14. The method of claim 11, wherein the impurities are supplied to the channel region using an ion implantation process, and wherein the amount of dose of impurity ions in the ion implantation process is about 1×10¹⁵/cm² to about 1×10¹⁷/cm².

15. The method of claim 11, wherein the impurities do not include n-type dopants and p-type dopants.

16. The method of claim 11, wherein defining the channel region and supplying the impurities to the channel region comprise:
forming a guide pattern on the substrate to define the channel region under the guide pattern;
forming an interlayer insulating layer on an entire surface of the substrate;
planarizing the interlayer insulating layer until a top surface of the guide pattern is exposed;
etching the guide pattern to form a groove; and
implanting impurities into the substrate including the groove.

17. The method of claim 16, wherein the guide pattern includes a dummy dielectric pattern and a dummy gate that are sequentially stacked, and wherein forming the groove includes removing the dummy gate.

18. The method of claim 17, after supplying the impurities, further comprising:
exposing the semiconductor substrate under the groove;
forming a gate dielectric layer on the exposed semiconductor substrate; and
forming a gate electrode on the gate dielectric layer and in the groove.

19. The method of claim 16, wherein the guide pattern includes a gate dielectric pattern and a gate electrode that are sequentially stacked, and wherein forming the groove includes removing an upper portion of the gate electrode and leaving a lower portion of the gate electrode.

20. A semiconductor device comprising:
a channel region defined in a semiconductor substrate and doped with first type dopants, the channel region including impurities;
a gate electrode disposed on the channel region; and
a source/drain formed in a substrate of both sides of the channel region and doped with second type dopants, wherein the first type dopants activated in the channel region are substituted with semiconductor atoms of a latticed structure and the impurities include interstitial impurities activated at an interstitial location of the latticed structure.
